(19) United States
(12) Patent Application Publication
(10) Pub. No.: US 2010/0163958 A1
(43) Pub. Date: Jul. 1, 2010

(54) SINGLE-POLY EEPROM CELL AND METHOD FOR FABRICATING THE SAME

(76) Inventor: Jong-Keon Choi, Bucheon-si (KR)

Correspondence Address: SHERR & VAUGHN, PLLC, 620 HERNDON PARKWAY, SUITE 320, HERNDON, VA, 20170, US

(21) Appl. No.: 12/646,485

(22) Filed: Dec. 23, 2009

(30) Foreign Application Priority Data
Dec. 31, 2008 (KR) 10-2008-0137737

(51) Int. Cl. H01L 27/115; H01L 21/8247

(52) U.S. Cl. 257/319; 438/211; 257/E21.68; 257/E27.103

(57) ABSTRACT

A single-poly EEPROM cell and a method for fabricating the same include a single floating gate formed in a single body; first and second read transistors sharing the single floating gate; and a control gate spaced apart from the first and second read transistors and overlapped with the floating gate. In the single-poly EEPROM structure, as a tunneling region is removed and a read PTR is additionally formed, a read margin can be enhanced without increase of overall area.

The present is application claims priority under 35 U.S.C. §119 to Korean Patent Application No., 10-2008-0137737 (filed on Dec. 31, 2008), which is hereby incorporated by reference in its entirety.

### BACKGROUND

An electrically erasable programmable read only memory (EEPROM) can erase and write data electrically and maintains data even in the case that a power voltage is turned off. Also, since erasure and programming can be performed electrically using tunneling in the EEPROM, a user can change information. However, the EEPROM has drawbacks in that its area is greater than that of an EPROM and its fabricating cost is higher than that of the EPROM as two transistors should be used to make one cell.

FIG. 1 is a perspective view illustrating a general single-poly EEPROM cell.

As illustrated in FIG. 1, first N well region 62 into which impurities are diffused, second N well region 64 into which impurities are diffused, and floating gate 70 are formed below control gate 60. First N well region 62 is located at one side of floating gate 70, and second N well region 64 is located at the other side of floating gate 70. Floating gate 70 is formed on and/or over first N well region 62 and second N well region 64 to form a single body. Second N well region 64 is driven as an erasure region. First N well region 62 acts as a source region, second N well region 64 may act as a drain region, and vice versa.

Control gate 60 is located on and/or over first N well region 62, and impurity regions, i.e., a P Moat region and an N Moat region, respectively exist within first N well region 62 and second N well region 64. Since floating gate 70 has a positive potential, control gate 60 uses a high positive voltage to program the EEPROM.

The operation of the aforementioned single-poly EEPROM cell is performed in such a manner that electrons are accumulated on or erased from floating gate 70, which is formed on and/or over first N well region 62 and second N well region 64 using Fowler-Nordhein (F-N) tunneling caused by electric field applied to a tunneling region of a thin oxide film.

In the single-poly EEPROM structure as illustrated in FIG. 1, an NMOS read transistor (NTR) exists. A current or voltage of the read transistor is measured to determine whether the cell is programmed or erased. In the case that a current or voltage of such a single transistor is read to determine whether the cell is programmed or erased, the program/erasure state depends on an absolute value of the single transistor. In this case, a problem occurs in that it may be determined in error whether the cell is programmed or erased as characteristics of the read transistor are shifted.

### SUMMARY

Embodiments relate to a single-poly EEPROM cell and a method for fabricating the same, in which a read margin and a sensing margin can be increased.

In accordance with embodiments, a single-poly EEPROM cell can include at least one of the following: a single floating gate formed in a single body; first and second read transistors sharing the single floating gate; and a control gate spaced apart from the first and second read transistors and overlapped with the floating gate.

In accordance with embodiments, a single-poly EEPROM cell can include at least one of the following: a substrate; a floating gate formed over the substrate, the floating gate having a main floating gate portion, a first floating gate portion extending from the main floating gate portion and a second floating gate portion extending from the main floating gate portion in a direction parallel to the first floating gate portion; a first transistors electronically connected to the floating gate by way of the first floating gate body; first and second read transistors electronically connected to the floating gate by way of the first floating gate body; and a control gate spaced apart from the first transistor and the second transistor and overlapped with the floating gate.

In accordance with embodiments, a method for fabricating a single-poly EEPROM cell can include at least one of the following: forming a deep N well region in a P type semiconductor substrate; forming a control gate to be spaced apart from the N well region; forming first and second read transistors within the deep N well region; and forming a single floating gate connected with the first and second read transistors.

In accordance with embodiments, in the single-poly EEPROM structure, as a tunneling region is removed and a read PTR is additionally formed, a read margin can be improved without increase of an area. Also, as NTR and PTR are simultaneously used as read transistors, a program state of the cell becomes contrary to an erasure state of the cell such that a sensing margin increases more than as generally done. Moreover, if the read NTR/PTR are surrounded by the deep N-well region, they can be isolated from the P type semiconductor substrate, and the read NTR can be used as the tunneling region.

### DRAWINGS

FIG. 1 a single-poly EEPROM cell.

Example FIGS. 2 and 3 illustrate a single-poly EEPROM cell, in accordance with embodiments.

### DESCRIPTION

Reference will now be made in detail to embodiments, examples of which are illustrated in the accompanying drawings. Wherever possible, the same reference numbers will be used throughout the drawings to refer to the same or like parts.

A single-poly electrically erasable programmable read only memory (single-poly EEPROM) in accordance with embodiments includes two transistors that may be formed as MOS transistors. The transistors are electrically isolated from each other by a device isolation film, and a floating gate acting as a gate electrode of the transistors are formed in a single body.

Example FIG. 2 is a plane view illustrating a single-poly EEPROM cell in accordance with embodiments.

As illustrated in example FIG. 2, first transistor 120 and second transistor 125 that share and are electrically connected to floating gate 100 exist. First transistor 120 has a read transistor (NTR) structure of NMOS, and is connected with one part 102a of floating gate 100. Source and drain regions, i.e., N/P impurity regions are formed below floating gate 100. Second transistor 125 has a read transistor (PTR) structure of PMOS, and is connected with the other part 102b of floating gate 100. Source and drain regions, i.e., N/P impurity regions are formed below floating gate 100. Floating gate 100 that connects first transistor 120 to second transistor 125 is overlapped with control gate 110. Control gate 100 is spaced apart from first transistor 120 and second transistor 125 by interposing a dielectric film therebetween.

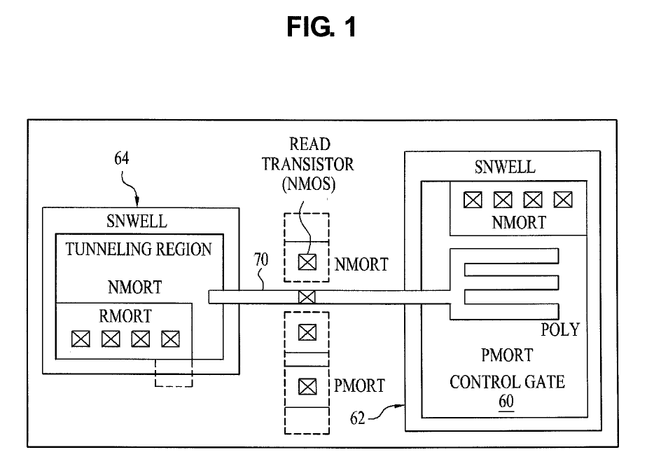

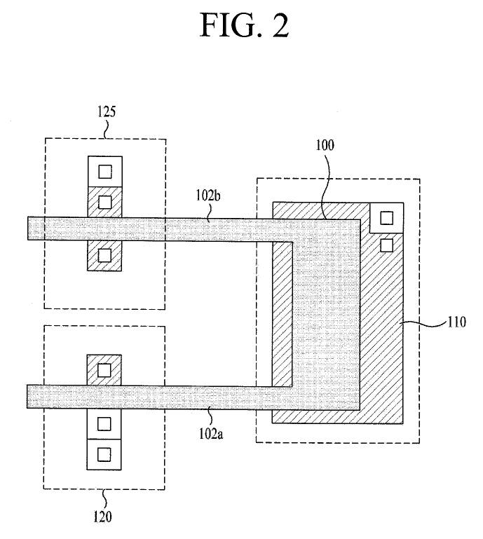

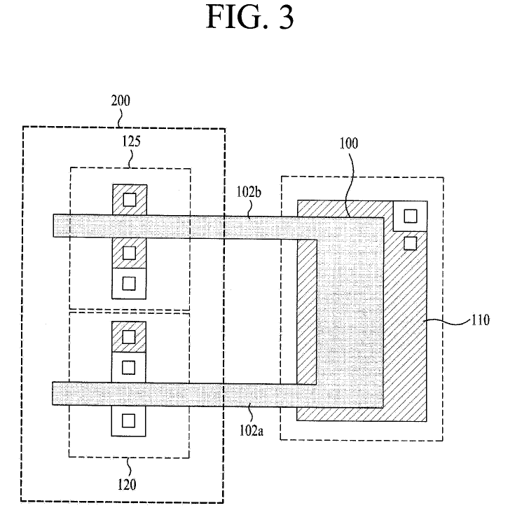

As described above, instead of a tunneling region of FIG. 1, second transistor 125 is additionally formed to simultaneously act as an electron tunneling region and the read transistor. If the cell is erased, a voltage Vt of the read NTR 120 descends and a voltage Vt of first transistor 125 ascends. Therefore, unlike a general structure that reads a single transistor only, both first transistor 120 and second transistor 125 are read to sense a current difference between the two transistors, such that the state of the cell can be identified. Also, since second transistor 125 is used as the tunneling region, an area is not increased.

Example FIG. 3 is a plane view illustrating a single-poly EEPROM cell in accordance with embodiments.

As illustrated in example FIG. 3, first transistor 120 and second transistor 125 that share floating gate 100 are formed. First transistor 120 has a read transistor (NTR) structure of NMOS, and is connected with one part 102a of floating gate 100. Source and drain regions, i.e., N/P impurity regions are formed below floating gate 100. Second transistor 125 has a read transistor (PTR) structure of PMOS, and is connected with the other part 102b of floating gate 100. Source and drain regions, i.e., N/P impurity regions are formed below floating gate 100. Floating gate 100 that connects first transistor 120 to second transistor 125 is overlapped with control gate 110. Control gate 100 is spaced apart from first transistor 120 and second transistor 125 by interposing a dielectric film therebetween. Deep N-well region 200 is formed below first transistor 120 and second transistor 125 by N type impurity ion implantation.

A method for fabricating the aforementioned single-poly EEPROM cell includes forming deep N well region 200 in a P type semiconductor substrate, forming control gate 110 spaced apart from N well region 200, forming first read transistor 120 and second read transistor 125 within deep N well region 200, and then forming floating gate 100 connected to first read transistor 120 and second read transistor 125.

As described above, instead of the tunneling region of FIG. 1, second read transistor 125 is additionally formed to simultaneously act as an electron tunneling region and the read PTR. Also, since first read transistor 120 and second read transistor 125 are formed to be surrounded by deep N-well region 200, the transistors can be isolated from the P type semiconductor substrate (P-sub). Moreover, the first read transistor 120 can also act as the tunneling region when the cell is erased. If the cell is programmed, a voltage Vt of first read transistor 120 ascends and a voltage Vt of the second read transistor 125 descends. If the cell is erased, a voltage Vt of first read transistor 120 descends and a voltage Vt of second read transistor 125 ascends.

As described above, in the single-poly EEPROM structure, as the tunneling region is removed and the read PTR is additionally formed, a read margin can be enhanced without increase of an area. Also, as the NTR and the PTR are simultaneously used as the read transistors, the program state of the cell becomes contrary to the erasure state of the cell, such that a sensing margin increases more than generally. Moreover, if the read NTR/PTR are surrounded by the deep N-well region, they can be isolated from the P type semiconductor substrate, and the read NTR can be used as the tunneling region.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a floating gate formed in a single body;
first and second read transistors electronically connected to the floating gate; and
a control gate spaced apart from the first and second read transistors and overlapped with the floating gate.

2. The apparatus of claim 1, further comprising a deep N-well region formed to surround the first and second read transistors.

3. The apparatus of claim 1, wherein the first read transistor comprises an NMOS transistor.

4. The apparatus of claim 3, wherein the second read transistor comprises a PMOS transistor.

5. The apparatus of claim 1, wherein the second read transistor comprises a PMOS transistor.

6. The apparatus of claim 1, wherein the apparatus comprises a single-poly EEPROM cell.

7. A method comprising:
forming a deep N well region in a P type semiconductor substrate;
forming a control gate spaced apart from the N well region;
forming first and second read transistors in the deep N well region; and then
forming a floating gate connected with the first and second read transistors.

8. The method of claim 7, wherein the first read transistor comprises an NMOS transistor.

9. The method of claim 8, wherein the second read transistor comprises a PMOS transistor.

10. The method of claim 7, wherein the second read transistor comprises a PMOS transistor.

11. An apparatus comprising:
a substrate;
a floating gate formed over the substrate, the floating gate having a main floating gate portion, a first floating gate portion extending from the main floating gate portion and a second floating gate portion extending from the main floating gate portion in a direction parallel to the first floating gate portion;
a first transistors electronically connected to the floating gate by way of the first floating gate body;
first and second read transistors electronically connected to the floating gate by way of the first floating gate body; and
a control gate spaced apart from the first transistor and the second transistor and overlapped with the floating gate.

12. The apparatus of claim 11, further comprising a deep N-well region formed in the substrate to surround the first transistor and the second transistor.

13. The apparatus of claim 11, wherein the first transistor comprises a first read transistor and the second transistor comprises a second read transistor.

14. The apparatus of claim 13, wherein the first read transistor comprises an NMOS transistor.

15. The apparatus of claim 14, wherein the second read transistor comprises a PMOS transistor.

16. The apparatus of claim 11, wherein the first transistor comprises an NMOS transistor.

17. The apparatus of claim 11, wherein the second transistor comprises a PMOS transistor.

18. The apparatus of claim 11, wherein the first transistor comprises an NMOS transistor and the second transistor comprises a PMOS transistor.

19. The apparatus of claim 11, wherein the apparatus comprises a single-poly EEPROM cell.

20. The apparatus of claim 1, wherein the substrate comprises a P type semiconductor substrate.
